(19) United States
(12) Patent Application Publication
(10) Pub. No.: US 2025/0298937 A1
(43) Pub. Date: Sep. 25, 2025

(54) Implementing an Expressive and Portable Inversion-of-Control Client Container Using Graph Algorithms

(71) Applicant: Dell Products, L.P., Hopkinton, MA (US)

(72) Inventor: Ruben Michel, Hopkinton, MA (US)

(21) Appl. No.: 18/615,311

(22) Filed: Mar. 25, 2024

(51) Int. Cl. G06F 30/20

(52) U.S. Cl. CPC G06F 30/20

(57) ABSTRACT

A Graphical User Interface (GUI) Inversion of Control Container (IoCC) is created by identifying a set of containing objects used to implement an application client, each containing object having at least one respective dependency, determining a respective generator for each respective dependency, and generating a wiring graph in which the nodes of the wiring graph are the containing objects and the dependencies, and the edges of the graph link each respective containing object to a respective resolved dependency. During runtime, the wiring graph is used to create instances of objects to be wired to software objects within the IoCC. The wiring graph is also used to recursively destroy objects and their injected dependencies to discard unused instances of objects when the GUI page for which the objects were created is no longer displayed.

### COPYRIGHT NOTICE

A portion of the disclosure of this patent document contains material which is subject to copyright protection. The copyright owner has no objection to the xerographic reproduction by anyone of the patent document or the patent disclosure in exactly the form it appears in the Patent and Trademark Office patent file or records, but otherwise reserves all copyright rights whatsoever.

### FIELD

This disclosure relates to computing systems and related devices and methods, and, more particularly, to a method and apparatus for implementing an expressive and portable inversion-of-control client container using graph algorithms.

### SUMMARY

The following Summary and the Abstract set forth at the end of this document are provided herein to introduce some concepts discussed in the Detailed Description below. The Summary and Abstract sections are not comprehensive and are not intended to delineate the scope of protectable subject matter, which is set forth by the claims presented below.

All examples and features mentioned below can be combined in any technically possible way.

Software applications can be divided into software components referred to herein as objects. Dependency injection is a programming technique, in which an object or function receives other objects or functions that it requires, instead of creating the object/function internally. Dependency injection thus separates the use of objects from creation of the objects, so that the different software components can be separately developed.

In traditional object-oriented programming, these types of relations were explicitly bound. For example, if a first object required a second object, the developer could explicitly wire the first object with an appropriate instance of the second object. Stated differently, if a class member is a reference, then the developer explicitly wires that reference with an appropriate instance.

In contrast, in Inversion of Control (IoC), wiring responsibility is transferred from the developer to an IoC container, IoCC, hosting the application. The wiring is dynamically bound since the selected wiring class is perhaps unknown at build time. This powerful abstraction allows developers to concentrate on their functional tasks, while delegating the involved wiring task to the IoCC. Under inversion of control, the framework first constructs an object such as a controller, and then passes control flow to it. With dependency injection, the framework also instantiates the dependencies declared by the application object and passes the dependencies into the object.

Enterprise Java environments feature sophisticated IoCCs, such as in Dagger, Guice, Helidon, Jakarta Enterprise Edition, Micronaut, PicoContainer, Quarkus, and Spring. Surprisingly, that sophistication is currently lacking in Graphical User Interface (GUI) environments used to implement application clients.

A “framework”, or “software framework”, as used herein, refers to a platform that provides a foundation for developing software applications. A framework may be conceptualized as a template of a working program that can be selectively modified by adding code. A GUI framework, accordingly, is a framework for creating Graphical User Interfaces, such as to be used to implement an application client. GUI frameworks must be upgraded every few years. If a GUI framework supports IoC at all, then that framework features proprietary IoC syntax and semantics. If the GUI framework changes, then the code that is written to implement the GUI likewise will need to be changed. Accordingly, code that should withstand a GUI-framework upgrade must therefore be independent of the GUI framework's particular IoC.

According to some embodiments, an application client Inversion of Control (IoC) Container (IoCC) is provided that is both expressive, and portable. As used herein, the term “expressive” is used to refer to the ability of the IoCC to create and inject multiple types of dependencies, such as beans, methods, and strings. The IoCC is also portable, since it is able to be used in multiple environments and is independent of the technology used to implement the GUI.

In some embodiments, an IoCC is implemented that determines dependencies at runtime and creates and injects the required objects, methods, and strings, to wire the software dependencies within the IoCC. In some embodiments, the IoCC determines dependencies of the software objects (referred to herein as the containing classes) and resolves the dependencies of the containing classes to generators. A wiring graph is created containing a set of containing classes and generators as nodes and edges linking the nodes based on the containing class dependencies.

At runtime, each time an instance of an object class is required to be created, the IoCC then traverses the portion of the graph containing the object class in a depth first manner, generating instances of the required objects, methods, and strings, to be injected to satisfy the dependencies. By providing an IoCC for the application client, it is possible to enable the application client to be created without relying on a GUI technology specific IoC. By creating a wiring graph, and using the wiring graph at runtime to quickly determine recursive dependencies for both creation and deletion of objects, it is possible for the IoCC to be used in a dynamic environment such as in connection with creating objects for a Graphical User Interface, in which many objects are frequently being created and destroyed as pages of the GUI are replaced.

In some embodiments, a method of implementing an Inversion of Control Container (IoCC), includes identifying a set of containing objects used to implement a Graphical User Interface of an application client, each containing object having at least one respective dependency, determining a respective generator for each respective dependency, generating a wiring graph in which the nodes of the wiring graph are the containing objects and the generators, and the edges of the graph link each respective containing object to a respective generator based on a resolved dependency, and using the wiring graph, at runtime, to recursively create instances of objects to be wired to software objects within the IoCC.

In some embodiments, the containing objects are base classes, and the respective dependencies are injection points to the base class. In some embodiments, the respective generators are classes, producer methods, or producer fields. In some embodiments, the wiring graph is an edge-labeled, directed graph represented by an adjacency list in which the nodes of the wiring graph are either classes or producer-method return types or producer-field types.

In some embodiments, the step of using the wiring graph, at runtime, to create instances of objects includes, for each instance of an object to be created, selecting an base class of the instance to be created, determining a location of the base class where the base class is included as a vertex in the wiring graph, determining a set of edges leading from the vertex to a set of generators, and recursively visiting each generator to create a respective injection into the instance of the object to be created from the base class. In some embodiments, the step of using the wiring graph, at runtime, to create instances of objects includes implementing a depth-first traversal of the wiring graph starting at the location of the base class where the base class is the vertex in the wiring graph. In some embodiments, the method further includes marking each node that is visited during the depth-first traversal of the wiring graph black and, after creating the instance of the object from the base class, marking each node that was visited during the depth-first traversal of the wiring graph white.

In some embodiments, the method further includes using the wiring graph, at runtime, to delete instances of objects that were previously created and wired to software objects within the IoCC. In some embodiments, deleting an instance of an object includes recursively deleting injections of the instance of the object. In some embodiments, deleting an instance of an object includes invoking any pre-destroy methods of the instance of the object, then recursively destroying injections to the instance of the object, then deleting the instance of the object, and then invoking any post-destroy methods of the instance of the object.

### BRIEF DESCRIPTION OF THE DRAWINGS

FIG. 1 is a block diagram of an example set of software objects included in an Inversion of Control Container (IoCC), according to some embodiments.

FIG. 2 is a flow chart of an example process of correlating containing class dependencies with generators to be used to wire the dependencies in the IoCC, according to some embodiments.

FIG. 3 is an example of a singleton bean written in TypeScript, according to some embodiments.

FIG. 4 is an example of a dependent bean written in TypeScript, according to some embodiments.

FIG. 5 is a graphical representation of a simplified example wiring graph, according to some embodiments.

FIG. 6 is a flow chart of an example process of generating a writing graph by the IoCC, according to some embodiments.

FIG. 7 is a graphical representation of another example wiring graph, according to some embodiments.

FIG. 8 is a flow chart of an example process of traversing the wiring graph at runtime to resolve injections for the dependencies of the containing classes, according to some embodiments.

FIG. 9 is a flow chart of an example process of creating a writing graph, according to some embodiments.

FIG. 10 is a flow chart of an example process of using the wiring graph, at runtime, to create objects as pages of the GUI are sequentially created within the IoCC, according to some embodiments.

FIG. 11 is a flow chart of an example process of destroying objects, at runtime, as pages of the GUI are sequentially deleted, according to some embodiments.

### DETAILED DESCRIPTION

Aspects of the inventive concepts will be described as being implemented using particular types of programming languages. Such implementations should not be viewed as limiting. Those of ordinary skill in the art will recognize that there are a wide variety of implementations of the inventive concepts in view of the teachings of the present disclosure.

Some aspects, features and implementations described herein may include machines such as computers, electronic components, optical components, and processes such as computer-implemented procedures and steps. It will be apparent to those of ordinary skill in the art that the computer-implemented procedures and steps may be stored as computer-executable instructions on a non-transitory tangible computer-readable medium. Furthermore, it will be understood by those of ordinary skill in the art that the computer-executable instructions may be executed on a variety of tangible processor devices, i.e., physical hardware. For ease of exposition, not every step, device or component that may be part of a computer or data storage system is described herein. Those of ordinary skill in the art will recognize such steps, devices, and components in view of the teachings of the present disclosure and the knowledge generally available to those of ordinary skill in the art. The corresponding machines and processes are therefore enabled and within the scope of the disclosure.

The terminology used in this disclosure is intended to be interpreted broadly within the limits of subject matter eligibility. The terms “logical” and “virtual” are used to refer to features that are abstractions of other features, e.g., and without limitation, abstractions of tangible features. The term “physical” is used to refer to tangible features, including but not limited to electronic hardware. For example, multiple virtual computing devices could operate simultaneously on one physical computing device. The term “logic” is used to refer to special purpose physical circuit elements, firmware, and/or software implemented by computer instructions that are stored on a non-transitory tangible computer-readable medium and implemented by multi-purpose tangible processors, and any combinations thereof.

Software applications can be divided into software components. Software components are also referred to as components. A service is a software component. A set of software components is one or more software components. A set of software components forms a software module. A software module may include other information and code, including code to couple software components within the software module as well as code that references software components from other software modules.

Illustrative embodiments recognize that dividing a software system into components helps to reduce the overall software system complexity, promotes software reuse and in general makes the software system robust. Software design based on certain software concepts or principles is called a software architecture.

A software architecture built using services as described above is called a service-oriented software architecture. A service-oriented software architecture is a software architecture in which software components with well-defined and exportable functions are modeled as services. The functions performed by a service can be presented to other software applications and services for their use. A method of presenting the service functions is called exporting the function. A function of a service that can be exported in this manner is called an exportable function. A well-defined function is a function that can be invoked with a set of known parameter data structures and returns results in known data structures. In object-oriented language such as Java or C++, a service is typically implemented as a class and the functions provided by the service are typically implemented as methods of the class.

In a software system, a service may perform complex business logic that references services from other software applications. Referencing other services in this manner forms dependency relations from a service to other services from other software applications. Thus, a dependent service is said to depend upon one or more dependency service, as described above.

Presently, the dependency from a dependent service to a dependency service is typically implemented in the class of the dependent service. A class of a service, such as a dependent service, is the definition of the service. In this type of implementation, the class of the dependent relies on an instance of the dependency service. An instance of a service, such as a dependency service, is a software object manifesting the service created based on the class of the service. The class of the dependent service then invokes a method of the instance of the class of the dependency service.

One design decision in managing service dependency is how a dependent service resolves the dependency at runtime. Resolving a dependency is resolving an instance of a dependency service, which is identifying the instance of the dependency service that is to be used. Runtime is the time of operation of the software system. Resolving a dependency at runtime is resolving the dependency at the time of operation of the software system.

Resolving and binding the dependent and dependency services is referred to herein as “wiring”. According to some embodiments, an Inversion of Control (IoC) Container is provided to wire dependent and dependency services. The term “container”, as used herein, is used to refer to a software component that manages, at runtime, a collection of other software objects.

Inversion-of-Control framework conceptualizes that a service should focus entirely on the service's business logic and not on how the service interfaces with other services. Inversion-of-Control framework further conceptualizes that a dependent service should not embed code containing either the implementation classes of the dependency services or methods for locating the dependency services. The Inversion-of-Control Container (IoCC) is configured to ensure that all dependency services of a dependent service are properly wired and that their object lifecycle is managed.

A design technique employed by the Inversion-of-Control framework for properly wiring dependencies is called dependency injection. Wiring the dependencies is connecting the dependent and dependency services and other objects according to the dependency amongst them. Dependency injection is the technique used by the Inversion-of-Control container to resolve and create the instances for all the dependency services of a dependent service, and inject these instances into the dependent service.

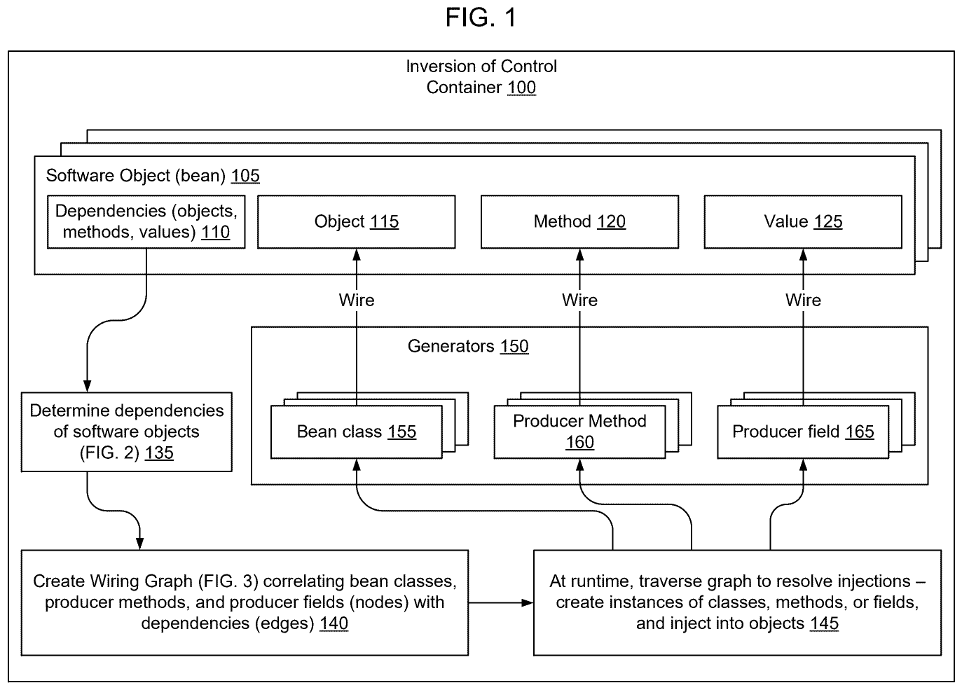

FIG. 1 is a block diagram of an example set of software objects included in an Inversion of Control Container (IoCC), according to some embodiments. As shown in FIG. 1, in some embodiments an Inversion of Control Container (IoCC) 100 is provided that is expressive and portable. In some embodiments, as described in greater detail herein, the IoCC is configured to create a wiring graph 140 defining the dependencies between dependent services and dependency services. At runtime, the IoCC 100 uses the wiring graph, specifically by traversing the wiring graph, to determine dependencies to perform dependency injection 145 to base classes to wire the software objects 105 used to implement the application client. For example, as shown in FIG. 1, in some embodiments the IoCC is expressive, in that the IoCC is able to create resolved injections of multiple types, namely objects 115, methods 120, and values 125, from multiple types of generators 150, including bean classes 155, producer methods 160, and producer fields 165. Additionally, since the dependency injection is being performed to base classes rather than to concrete classes, it is possible to select the type of injections to be implemented to the base class based on a configuration file associated with the IoCC. For example, a text configuration file may specify at startup of the IoCC the format of object that should be injected to the base class by the IoCC at runtime.

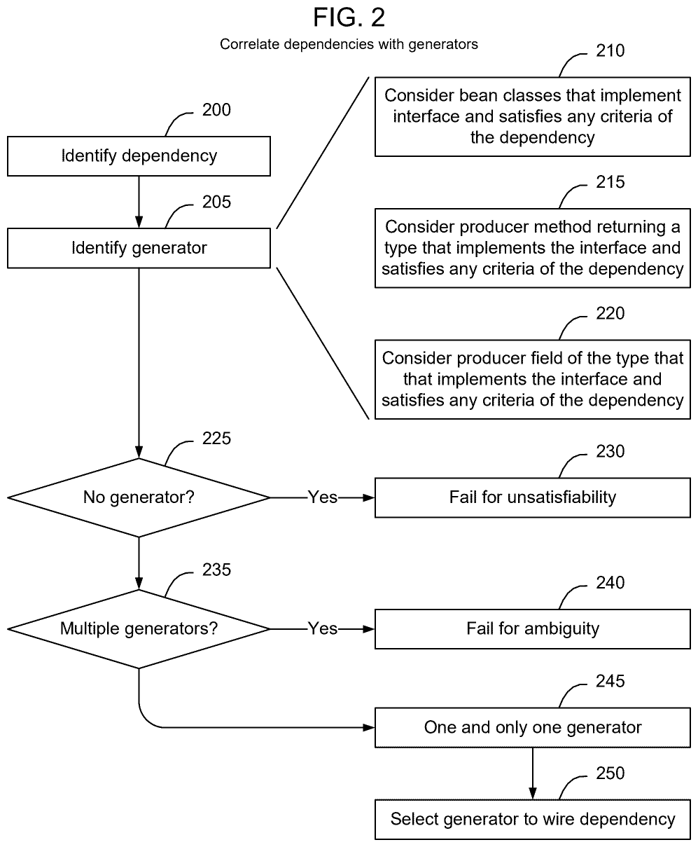

FIG. 2 is a flow chart of an example process of correlating dependencies with generators to be used to wire the dependencies in the IoCC, according to some embodiments.

In traditional programming, if class A has a relation b of type interface IB, denoted A.b, then the developer explicitly wires that relation through an assignment, such as, A.b=new B( ), where the class B implements the interface IB and features a default no-argument constructor. By contrast, with Inversion of Control, the IoCC wires such relations at runtime according to various criteria. In some embodiments, as shown in FIG. 2, when a dependency is identified (block 200), the IoCC considers one of three generators (block 205). First, the IoCC considers all the bean classes that implement the interface IB and satisfy various criteria (block 210). Next, the IoCC considers each producer method returning a type that implements IB and satisfies the various criteria (block 215). Producer methods are necessary for wiring both primitive types and classes that are not bean classes. Finally, the IoCC considers each producer field of a type that implements IB and satisfies the various criteria (block 220). If the IoCC identifies no such generator (a determination of YES at block 225), then the IoCC fails due to unsatisfiability (block 230). If, however, the IoCC identifies more than one such generator (a determination of YES at block 235), then the IoCC fails due to ambiguity (block 240). Otherwise (in response to a determination of both NO at block 225 and NO at block 235), the IoCC declares success and identifies the one and only one generator (block 245). The wiring graph is updated to include the determined generator, and that generator is then used, at runtime, to wire the dependency (block 250).

In some embodiments, at runtime, the IoCC instantiates a wiring-instance b in one of three ways. First, if the generator is a bean class B (identified in block 210), then the IoCC invokes B's default constructor, b=new B( ). As described below, bean classes are defined as having a no-argument constructor. Second, if the generator is a producerMethod( ) (identified in block 215), then the IoCC invokes that method, b=producerMethod( ). Third, if the generator is a producer field (identified in block 220), then the IoCC simply assigns b=producerField.

Having generated the wiring-instance b, the IoCC recursively wires all of b's injections. Thereafter, the IoCC invokes all of b's post-construct methods. Finally, the IoCC wires b into the field injection A.b, by the assignment A.b=b. This is how the IoCC solves the wiring problem.

As described in greater detail herein, in some embodiments the IoCC uses a graph algorithm for wiring singleton and dependent beans into field injections. The IoCC also uses the graph algorithm to implement method-parameter injections and constructor-parameter injections to enhance the expressivity of the IoCC.

As described in greater detail, in some embodiments the IoCC creates a wiring graph that is an edge-labeled, directed graph represented by an adjacency list. The graph's nodes are either bean classes or producer-method return types or producer-field types. The graph's edges match closely resolved injections. In a resolved injection, the wiring type IB has been resolved to the actual implementing type B. Accordingly, the edge corresponding to that resolved injection has the containing bean class as source and the resolved class B as target. The edge's label is a pair consisting of the field's name and either a producer (method producer or field producer), if a producer generates the wired instance, or null otherwise (if a bean class is used to generate the injected object).

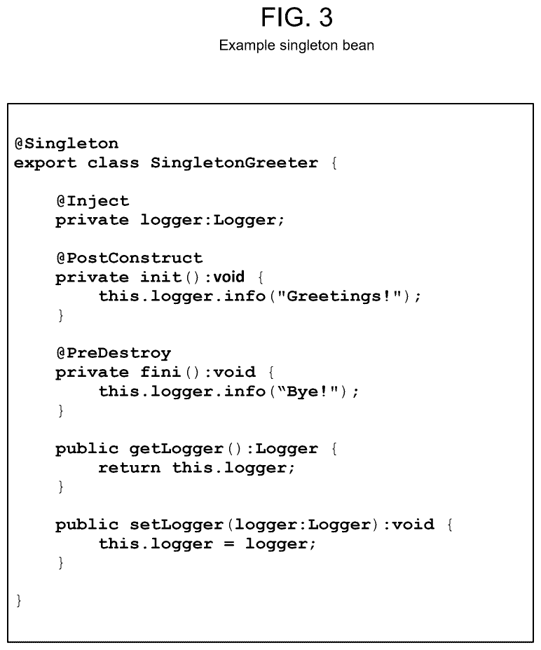

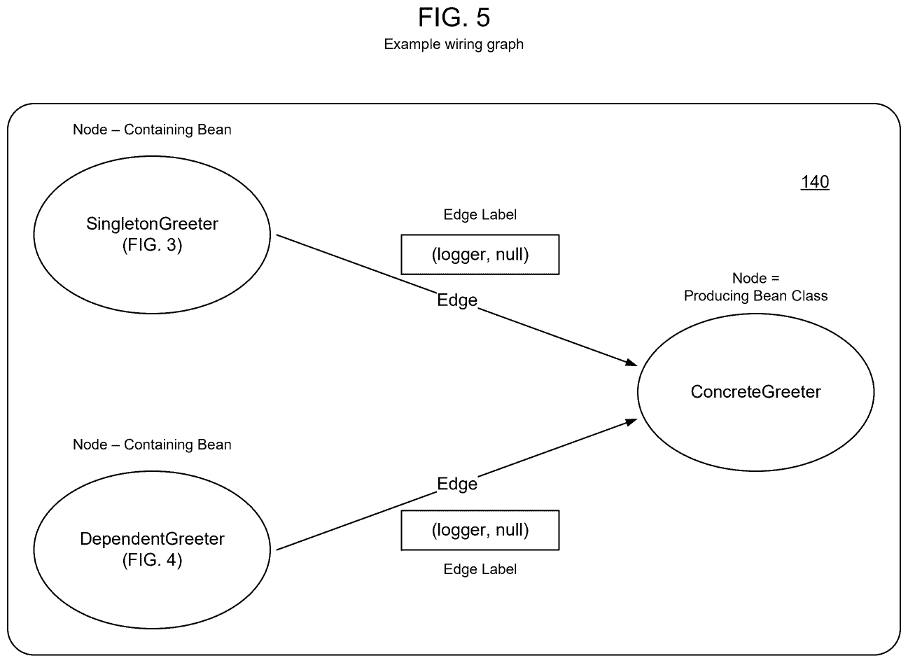

FIG. 3 is an example of a singleton bean written in TypeScript, according to some embodiments. As shown in FIG. 3, in TypeScript, a bean class is a TypeScript class satisfying three conditions: (1) the bean class has a public, no-argument constructor; (2) each bean-class property is private; and (3) each bean-class property is exposed through a public getter and a public setter. A bean is an instance of a bean class. According to some embodiments, the IoCC described herein supports a variety of bean types. FIG. 5 shows one example bean type which is a singleton, which is described in detail by the Gang of Four's (GoF's) Singleton Design Pattern.

FIG. 3 shows an example bean class named, in this example, SingletonGreeter. As shown in FIG. 3, the SingletonGreeter class is a bean class. Specifically, since SingletonGreeter has no explicit constructor, TypeScript inserts a default no-argument constructor. In addition, SingletonGreeter has a single property, logger, which is private. Finally, SingletonGreeter has both a public getter and a public setter for the logger property. Therefore, the SingletonGreeter class is indeed a bean class.

In FIG. 3, the elements @Singleton, @Inject, @PostConstruct, and @PreDestroy are TypeScript decorators clearly indicating their purpose. Decorators, as that term is used herein, are a special kind of declaration that can be attached to a class declaration, method, accessor, property, or parameter. The singleton bean class shown in FIG. 3 features a field injection (@inject private logger.Logger). The IoCC creates an appropriate logger bean and wires that bean into SingletonGreeter.logger. Notice that the developer simply declares the logger, but the IoCC instantiates that logger. Next, the bean class features a post-construct init( ) method, which the IoCC invokes after instantiating a bean and completing all wiring. In FIG. 3, the post-construct method causes the bean to generate the word “Greetings!”. Finally, the bean class also features a pre-destroy fini( ) method, which the IoCC invokes before un-wiring and destroying the bean.

The IoCC creates at most one singleton instance of a particular bean class, hence the name. Consequently, the IoCC wires that same instance at all injections associated with that bean class. If no such injection exists, then no bean is instantiated. However, startup singletons are always instantiated regardless of whether they are required to be used in any injections. To demonstrate a singleton bean, consider a software client's connection to a server. That connection must remain accessible across the entire client for as long as the client operates. That connection is dropped before the client terminates. Therefore, that client-to-server connection is naturally encapsulated in a singleton bean, such that any other object that requires injection of a bean to reference the connection to the server will be provided with the IoCC's instance of the singleton bean.

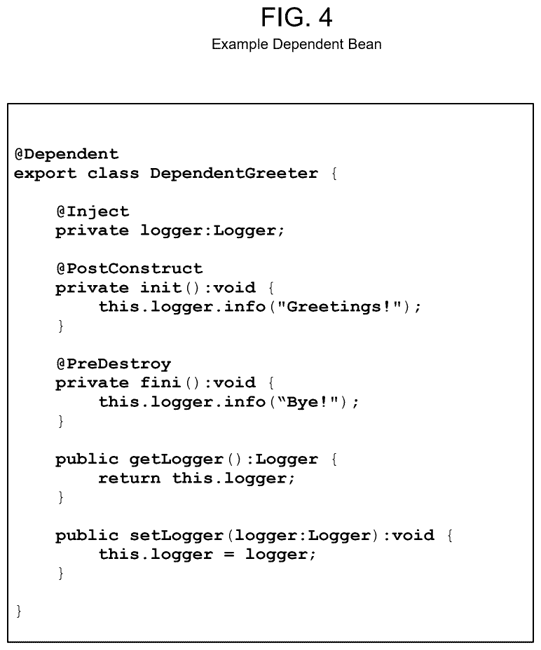

FIG. 4 is an example of a dependent bean written in TypeScript, according to some embodiments. Dependent beans, like singleton beans, are created from a TypeScript class satisfying the same three conditions: (1) the bean class has a public, no-argument constructor; (2) each bean-class property is private; and (3) each bean-class property is exposed through a public getter and a public setter. A dependent bean is an instance of a dependent bean class. Unlike singleton beans, the IoCC creates a new dependent bean each time it wires a respective containing bean. Also, before destroying the containing bean, the IoCC destroys that dependent bean. Thus, a dependent bean and its containing bean have matching lifecycles. An example of a dependent bean might be a logger used in a bean, as indicated in FIG. 4. The logger should retain its containing bean's class name, to emit identifiable-log messages, while the containing bean operates. As soon as the containing bean is destroyed, that logger becomes superfluous. Thus, that logger is naturally encapsulated in a dependent bean and is destroyed when the containing bean is destroyed.

Singleton beans and dependent beans may be stateful, in which the bean maintains state among method calls, or stateless, in which the bean discards its state among calls. Additionally, depending on the implementation of the IoCC, a bean may be persistable, such that the bean can survive IoCC shutdown by persisting to some media. Similarly, a bean may be a database-persistable, such that the bean persists to a database. Persistable and database-persistable beans enable the IoCC to reincarnate such beans on startup. Additionally, depending on the implementation of the IoCC, to save memory, an IoCC may passivate to storage an idle passivatable bean and reincarnate that bean on demand thereafter. For example, in instances where a bean requires significant amount of browser memory, the bean may be passivated to browser storage and then reincarnated on demand when needed.

To simplify the description of the IoCC, the description will focus specifically on how the IoCC wires dependencies using singleton and dependent beans, which play a central role in GUI development. In addition to field injections (wiring singleton and dependent beans into containing beans), the IoCC can also wire method-parameter injections and constructor-parameter injections using these same techniques. Without loss of generality, the description will concentrate on field injections and, for conciseness, refer to them simply as injections.

In some embodiments, as noted above, the IoCC determines dependencies and generates a wiring graph describing the set of dependencies to be wired. In a large client application, the client may have thousands of containing beans and thousands of generators. Further generators may themselves be containing beans having dependencies that need to be wired. In some embodiments, the IoCC first creates a wiring graph describing the set of dependencies and then, at runtime, uses the wiring graph by traversing the wiring graph to create instances of objects, methods, and fields for injection into the containing beans.

FIG. 5 is a graphical representation of a simplified example wiring graph, according to some embodiments. In FIG. 5, the example wiring graph includes three nodes, that include the singleton bean of FIG. 3, the dependent bean of FIG. 4, and a producing bean class ConcreteLogger. In the example shown in FIG. 5 the graph includes two edges—a first edge between SingletonGreeter and ConcreteGreeter, and a second edge between DependentGreeter and ConcreteGreeter. Specifically, as noted above, both the SingletonGreeter bean class and the DependentGreeter bean class are containing classes, with each of these bean classes having a dependency and requiring injection of a logger as noted by the inclusion of the injection in both beans: (@inject private logger.Logger). In FIG. 5, it is assumed that ConcreteLogger is a bean class selected as the generator of the required logger object and is the bean class that implements the Logger interface. The example graph shown in FIG. 5 thus has three nodes—SingletonGreeter, DependentGreeter, and ConcreteLogger. The edges of the graph correspond to the resolved injections, where each edge has the containing bean class as the source and the resolved class as the target.

Although not shown in FIG. 5, in some embodiments the IoCC supports not only field injections of class objects, but also supports producer methods and producer fields. In some embodiments, each edge label includes a pair consisting of the field's name and either a producer, if a producer generates the wired instance, or null otherwise (if a bean class is used as the generator to generate a corresponding object for the field injection).

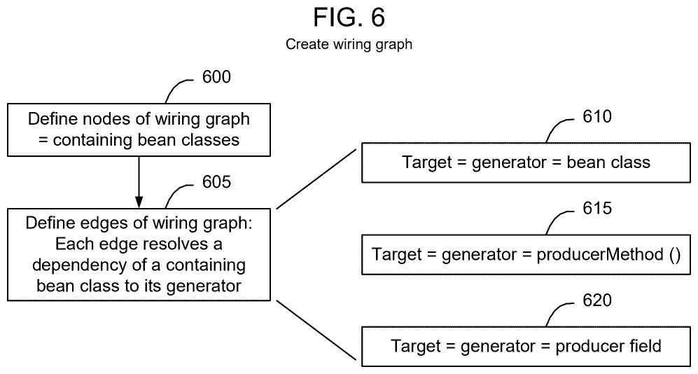

FIG. 6 is a flow chart of an example process of generating a writing graph by the IoCC, according to some embodiments. As shown in FIG. 6, in some embodiments the IoCC defines nodes of the wiring graph to include containing bean classes (block 600) and the concrete injected classes. The IoCC defines edges of the wiring graph as connecting generators (edge targets) to the dependencies of the containing beans (block 605). For example, as described above in connection with FIG. 2, in some embodiments the IoCC seeks to identify a specific generator for each determined dependency of a containing bean. Accordingly, as shown in FIG. 6, the edge targets might be bean classes (block 610), producerMethod( ) (block 615), or producerField (block 620). The wiring graph, is accordingly an edge-labeled, directed graph, represented by an adjacency list.

In some embodiments, the IoCC creates a wiring graph containing each class of objects and its respective identified injections. For example, a graphical user interface for a large application might support thousands of object classes, each of which may have no injection, one injection, or multiple injections. Each of the injections, recursively, might have their own injections. The IoCC generates a wiring graph describing these injections such that, during runtime if an object of a particular class is required to be created, the IoCC can use the wiring graph to determine the related objects that need to be recursively created and the producer method that needs to be called or the producer field that needs to be used to generate an instance of the required object class.

Notice that the generated wiring graph is defined in terms of TypeScript classes. During runtime, for wiring, the IoCC requires creation of class instances, not classes. To create those instances at runtime, the IoCC carefully visits the wiring graph using an instance-producer visitor. Conversely, to destroy such created instances, the IoCC again visits that same wiring graph, but using an instance-destroyer visitor instead. Each time an instance of an object of a particular object class is to be created, the IoCC uses the wiring graph to recursively build the required object. Each time an instance particular object class is to be destroyed, each of the injected dependent dependencies is also destroyed. Singletons, however, are destroyed only if explicitly requested.

In some embodiments, these two visitors (instance-producer visitor and instance-destroyer visitor) are inspired by a white-gray-black vertex-coloring algorithm underpinning a Depth First Search. A vertex is colored white when it is first visited. A vertex is colored gray if it has already been visited, but some of its out-edges have yet to be visited. Finally, a vertex is colored black if it has been completely visited, meaning that all its out-edges have been visited. When an object is to be created, the visitor gradually visits the wiring graph associated with the object, properly coloring and recoloring vertices while traversing edges. In Depth First Search, black vertices are never recolored. In contrast, here, whenever a vertex representing a dependent bean class turns black, meaning that the vertex and all the out edges from the vertex have been completely visited, that vertex immediately reverts to white. Therefore, the next time that vertex is visited, for example during runtime if another instance of a given object class is required to be created, a renewed graph visit begins from that white vertex, thereby instantiating a brand-new dependent bean.

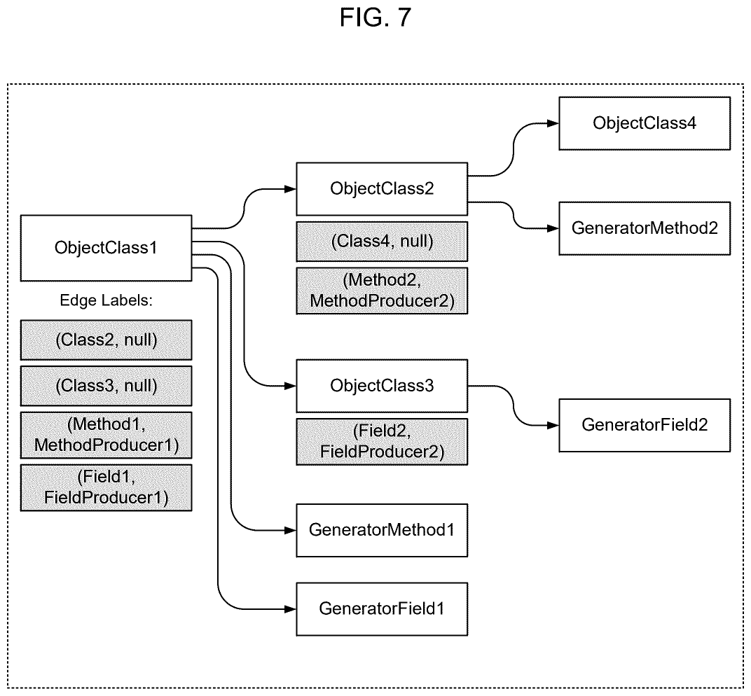

FIG. 7 is a block object of an example wiring graph, according to some embodiments. As shown in FIG. 7, in some instances object dependencies will require creation of beans which themselves have dependencies. For example, in FIG. 7, ObjectClass1 has dependencies that include ObjectClass2 and ObjectClass3. ObjectClass2 has a dependency on ObjectClass4. The ObjectClasses likewise have dependencies on ProducerMethods and ProducerFields. By creating a wiring graph that contains all the dependencies specified as edges, it is possible to manage all the complex interrelated dependencies to ensure that dependencies are recursively created at runtime to include each of the required objects/methods/field injections.

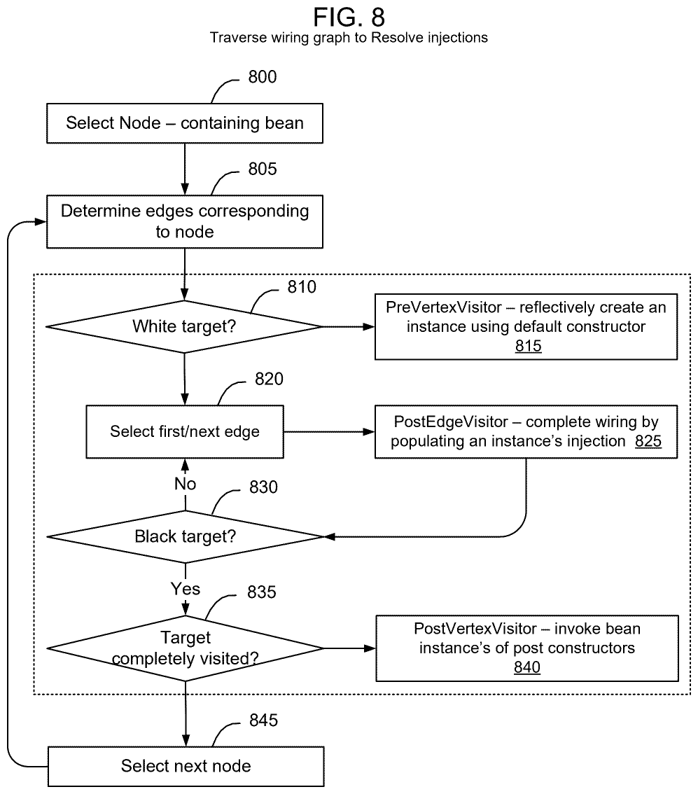

FIG. 8 is a flow chart of an example process of traversing the wiring graph to resolve bean injections for the dependencies of the containing classes, according to some embodiments. As shown in FIG. 8, in some embodiments the visitor selects a node of the graph (block 800) which, as noted above, in some embodiments represents a containing bean that has at least one dependency that needs to be wired by having the IoCC generate and inject either an object, a bean or primitive type.

The visitor then determines the edges for the selected node (block 805). For each edge, the visitor determines whether the target is white, gray, the target is black, or the target has been completely visited. If the target is white (a determination of YES at block 810), the visitor uses a preVertexVisit( ) method to reflectively create an instance (block 815). For example, when the instance to be created is a bean, the preVertexVisit( ) method returns either the single instance of the singleton bean or causes creation of a new instance of a dependent bean. When the generator is a producerMethod( ), the preVertexVisit( ) method calls the required method to obtain the required value from the method. When the generator is a producderField, the preVertexVisit( ) method invokes the generator and returns the required value from the generator.

Each edge from the vertex is then visited, by selecting a first edge from the vertex (block 820), creating the injection associated with the edge, and a postEdgeVisit( ) method is used to complete wiring of the injection for the edge by populating the instance's injection. A determination is then made if all edges have been visited—i.e. if the vertex has been colored black (block 830). In response to a determination that not all edges from the vertex have been visited (a determination of NO at block 830), the process returns to block 820 where a next edge is selected. The postEdgeVisit( ) method is thus iteratively called, each time wiring a respective instance, until all instances have been wired (a determination of YES at block 830).

When the target has been completely visited (block 835), the visitor invokes a postVertexVisit( ) method to invoke the target bean instances' post constructor methods (block 840). For example, in FIG. 3 the SingletonGreeter bean included a post constructor method to output “Greetings!”. The next node is then selected (block 845).

In instances where an object class requires injection of a singleton bean, once the IoCC has created the singleton bean, the IoCC contains a reference to the location of the singleton bean and simply uses the singleton bean any time an object is created that requires injection of the singleton bean. To do this, the wiring graph nodes that are singleton beans are colored black and not recolored white, thus preventing the IoCC from revisiting/recreating the singleton bean.

In some embodiments, the PreVertexVisit step (block 815) reflectively creates an instance in one of the three ways described above, either by invoking the default constructor, or by using a producer method, or by using a producer field. After implementing the PreVertexVisit step, the PostEdgeVisit( ) method (block 825) performs the actual wiring. The PostVertexVisit method (block 835) then reflectively invokes any post constructors of both the containing bean and contained beans.

In summary, while visiting the wiring graph, the graph visitor first creates an instance of the containing bean, then it populates all the instance's injections, and, finally, it involves the instance's post constructors.

The instance-destroyer visitor is implemented similarly. However, while the instance-producer visitor places the visiting steps in a queue, the instance-destroyer visitor places the visiting steps in a stack.

In some embodiments, the GUI sequentially creates pages for display to the user. Each page of the GUI requires creation of a set of objects of various object classes. When a page of the GUI is replaced, the previous set of objects associated with the previous GUI page need to be destroyed. Since the objects contain instances of other objects (dependencies), those injected objects similarly need to be destroyed. Each instance of an object requires the use of memory and, if the objects were not destroyed, the unused objects would continue occupying memory. Accordingly, in some embodiments, prior to destroying an object, the IoCC invokes the object's pre-destroy methods, recursively destroys each of the injected objects, and only once all the injected objects have been recursively destroyed, destroys the objects. This ensures that the IoCC cleans up the object, as well as cleaning up recursively all objects that have been created to be injected into the object that was selected for destruction.

By implementing an IoCC that is independent of GUI framework IoCC, it is possible to isolate the Client created using the GUI framework from being reliant on the GUI framework's IoCC. Accordingly, in instances where it is desirable to transition a software client from one GUI framework to another GUI framework, such as to transition the client from AngularJS to Angular, it is possible to do so independent of the GUI framework's IoCC, thus for example, avoiding porting the client from the AngularJS IoCC to the Angular IoCC, which would be a tedious and time-consuming process. Further, the IoCC described herein is sufficiently expressive, supporting not only field injections (objects) but also method-parameter injections and constructor-parameter injections, to enable multiple types of dependencies to be injected at runtime.

Although an example IoCC was described herein in which the example was written in TypeScript, it should be understood that other sufficiently expressive programming languages such as Python could also be used. Further, to facilitate adoption, the IoCC presented herein mirrors in TypeScript a small subset of Jakarta Enterprise Edition's syntax and semantics. It should be understood that the IoCC could be adapted to mirror another programming language's syntax and semantics as well.

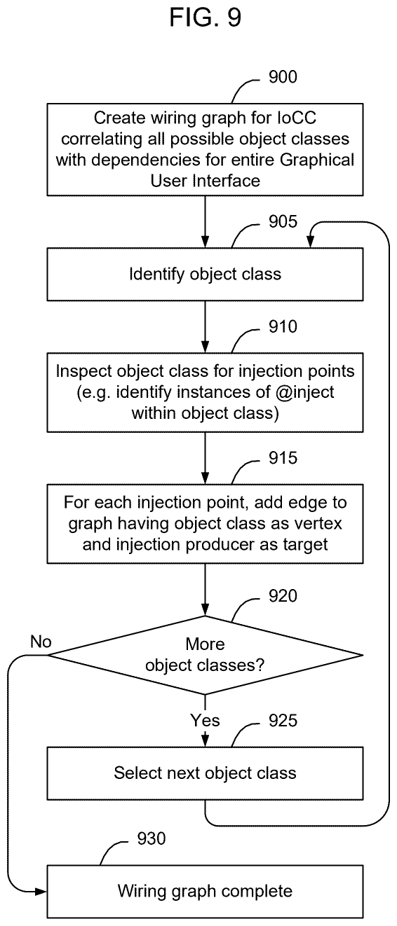

FIG. 9 is a flow chart of an example process of creating a writing graph, according to some embodiments. As shown in FIG. 9, in some embodiments a wiring graph is created for the IoCC container correlating all possible object classes with dependencies for the entire Graphical User Interface (GUI) (block 900). In some embodiments, an object class of the GUI is identified (block 905) and the object class is inspected to determine any injection points contained within the object class (block 910). Injection points may be identified in different ways, depending on the type of object. For example, in some embodiments, an injection point may be identified by identifying instances of “@inject” within the object class, although the particular manner of determining injection points will depend on the particular implementation. In some embodiments, for each injection point, an edge is added to the graph having the object class as a vertex and an injection producer as the target (block 915). Once the injection points of the selected object class are fully determined, a determination is then made as to whether there are more object classes of the GUI (block 920). In response to a determination that there are additional object classes (a determination of YES at block 920) the next object class is selected (block 925) to determine the injection points of the object class (blocks 905-915). Once all object classes have been inspected (a determination of NO at block 920), creation of the wiring graph is complete (block 930).

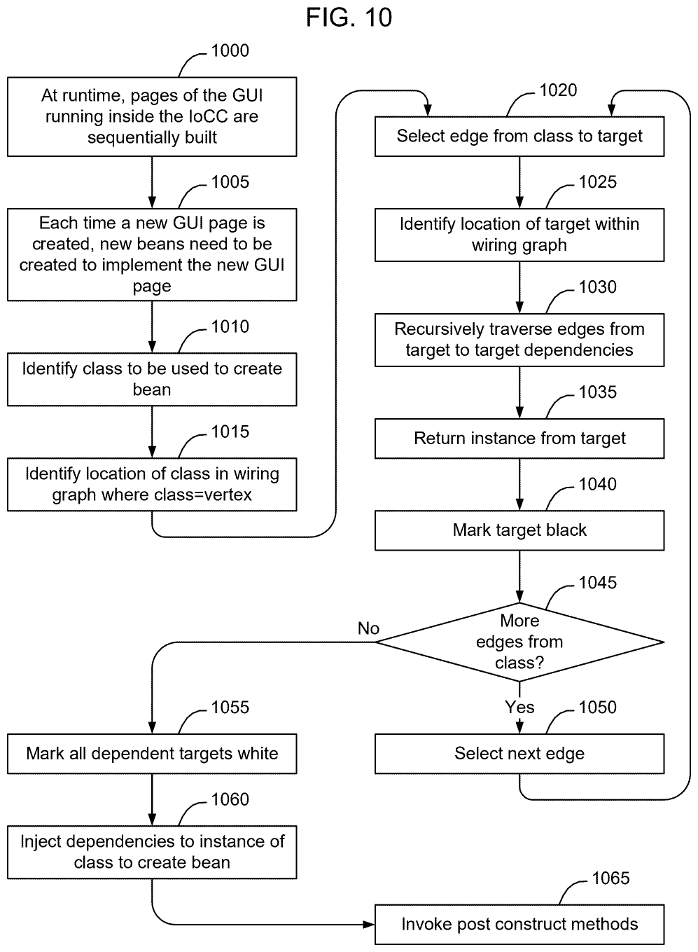

FIG. 10 is a flow chart of an example process of using the wiring graph, at runtime, to create objects as pages of the GUI are sequentially created within the IoCC, according to some embodiments. As shown in FIG. 10, at runtime, pages of the Graphical User Interface (GUI) that is running inside the IoCC are sequentially built (block 1000). Each time a new GUI page is created, new beans need to be created to implement the new GUI page (block 1005). Accordingly, for each bean that is to be created, the class to be used to create the bean is identified (block 1010). The location of the bean class in the wiring graph is then determined, where the bean class is a vertex in the wiring graph (block 1015).

The injections required by the bean class are then determined from the edges of the wiring graph that has the bean class as the vertex. For example, as shown in FIG. 10, a first edge is selected from the bean class to a target (block 1020). The location of the target is identified within the writing graph (1025), and the process recursively traverses edges from the target to the target dependencies (block 1030) until an instance has been created for injection into the bean. The instance is returned from the target (block 1035) and the target is marked black (block 1040). A determination is then made if there are additional edges from the class to additional targets (block 1045). In response to a determination that there are additional edges to be traversed (a determination of YES at block 1045), the process returns to block 1020 to select a subsequent edge. The process iterates marking each visited target black until all edges have been traversed (a determination of NO at block 1045) at which point all injections have been created and injected into the instance of the bean class. All of the visited targets are marked white (other than singletons) (block 1055) and the created dependencies are injected into the instance of the bean class to create a bean for the GUI from the bean class (block 1060). Any post-construction methods are then invoked (block 1065) and the process returns to block 1010 to select a next bean for creation for the GUI page.

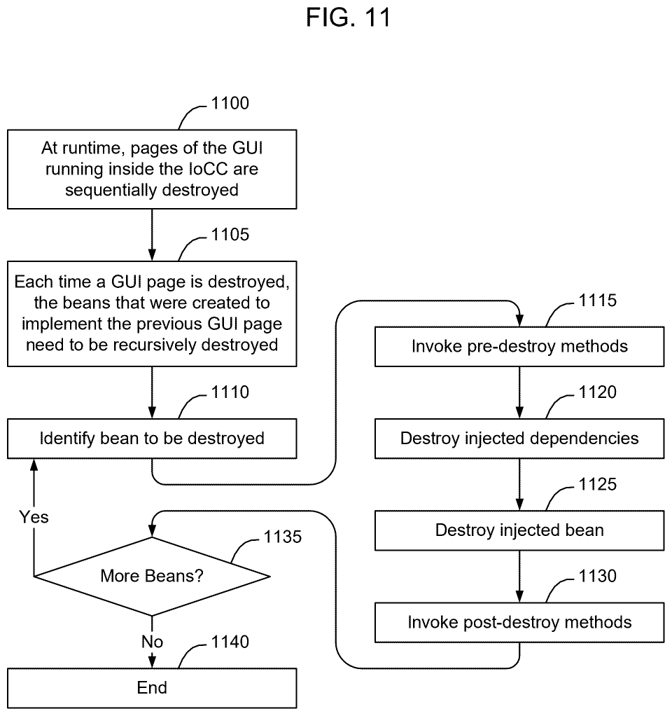

FIG. 11 is a flow chart of an example process of destroying objects, at runtime, as pages of the GUI are sequentially deleted, according to some embodiments. As shown in FIG. 11, at runtime, pages of the GUI running inside the IoCC are sequentially destroyed (block 1100). For example, if the GUI is initially showing one screen that enables access to and control over a first aspect of a software application, and the GUI is changed to show a new screen that enables access and control over a second aspect of the software application, the objects that were created for the first screen will need to be recursively destroyed to reduce the amount of memory used to store the previously created objects that are no longer being used (block 1105).

Accordingly, when a page of the GUI is destroyed, in some embodiments the beans that were created for the previous page of the GUI that need to be destroyed are identified (block 1110). Note, in this regard, that the previous page of the GUI might include dependent beans and singleton beans. Singleton beans are only destroyed if explicitly required to be destroyed. Otherwise, the singleton beans are preserved by the IoCC. For each bean that is identified to be destroyed, in some embodiments the IoCC invokes any pre-destroy methods of the bean (block 1115), recursively destroys the injected dependencies of the bean (block 1120), then destroys the injected bean (block 1125) and finally invokes any post-destroy methods (block 1130). After destroying the bean, a determination is made as to whether there are additional beans of the GUI page that need to be destroyed (block 1135). In response to a determination that there are additional beans to be destroyed (a determination of YES at block 1135), the process returns to block 1110 where a subsequent bean is selected. The selected bean and its injections are hence recursively destroyed (blocks 1115-1130). Once all beans of the GUI page have been destroyed (a determination of NO at block 1135) the process ends (block 1140).

The methods described herein may be implemented as software configured to be executed in control logic such as contained in a CPU (Central Processing Unit) or GPU (Graphics Processing Unit) of an electronic device such as a computer. In particular, the functions described herein may be implemented as sets of program instructions stored on a non-transitory tangible computer readable storage medium. The program instructions may be implemented utilizing programming techniques known to those of ordinary skill in the art. Program instructions may be stored in a computer readable memory within the computer or loaded onto the computer and executed on computer's microprocessor. However, it will be apparent to a skilled artisan that all logic described herein can be embodied using discrete components, integrated circuitry, programmable logic used in conjunction with a programmable logic device such as a FPGA (Field Programmable Gate Array) or microprocessor, or any other device including any combination thereof. Programmable logic can be fixed temporarily or permanently in a tangible non-transitory computer readable medium such as random-access memory, a computer memory, a disk drive, or other storage medium. All such embodiments are intended to fall within the scope of the present invention.

Throughout the entirety of the present disclosure, use of the articles “a” or “an” to modify a noun may be understood to be used for convenience and to include one, or more than one of the modified nouns, unless otherwise specifically stated. The term “about” is used to indicate that a value includes the standard level of error for the device or method being employed to determine the value. The use of the term “or” in the claims is used to mean “and/or” unless explicitly indicated to refer to alternatives only or the alternatives are mutually exclusive, although the disclosure supports a definition that refers to only alternatives and to “and/or.” The terms “comprise,” “have” and “include” are open-ended linking verbs. Any forms or tenses of one or more of these verbs, such as “comprises,” “comprising,” “has,” “having,” “includes” and “including,” are also open-ended. For example, any method that “comprises,” “has” or “includes” one or more steps is not limited to possessing only those one or more steps and also covers other unlisted steps.

Elements, components, modules, and/or parts thereof that are described and/or otherwise portrayed through the figures to communicate with, be associated with, and/or be based on, something else, may be understood to so communicate, be associated with, and or be based on in a direct and/or indirect manner, unless otherwise stipulated herein.

Various changes and modifications of the embodiments shown in the drawings and described in the specification may be made within the spirit and scope of the present invention. Accordingly, it is intended that all matter contained in the above description and shown in the accompanying drawings be interpreted in an illustrative and not in a limiting sense. The invention is limited only as defined in the following claims and the equivalents thereto.

What is claimed is:

1. A method of implementing an Inversion of Control Container (IoCC), comprising:
identifying a set of containing objects used to implement a Graphical User Interface of an application client, each containing object having at least one respective dependency;
determining a respective generator for each respective dependency;
generating a wiring graph in which the nodes of the wiring graph are the containing objects and the generators, and the edges of the graph link each respective containing object to a respective generator based on a resolved dependency; and
using the wiring graph, at runtime, to recursively create instances of objects to be wired to software objects within the IoCC.

2. The method of claim 1, wherein the containing objects are base classes, and wherein the respective dependencies are injection points to the base class.

3. The method of claim 1, wherein the respective generators are classes, producer methods, or producer fields.

4. The method of claim 1, wherein the wiring graph is an edge-labeled, directed graph represented by an adjacency list in which the nodes of the wiring graph are either classes or producer-method return types or producer-field types.

5. The method of claim 1, wherein the step of using the wiring graph, at runtime, to create instances of objects comprises, for each instance of an object to be created, selecting an base class of the instance to be created, determining a location of the base class where the base class is included as a vertex in the wiring graph, determining a set of edges leading from the vertex to a set of generators, and recursively visiting each generator to create a respective injection into the instance of the object to be created from the base class.

6. The method of claim 5, wherein the step of using the wiring graph, at runtime, to create instances of objects comprises implementing a depth-first traversal of the wiring graph starting at the location of the base class where the base class is the vertex in the wiring graph.

7. The method of claim 6, further comprising marking each node that is visited during the depth-first traversal of the wiring graph black and, after creating the instance of the object from the base class, marking each node that was visited during the depth-first traversal of the wiring graph white.

8. The method of claim 1, further comprising using the wiring graph, at runtime, to delete instances of objects that were previously created and wired to software objects within the IoCC.

9. The method of claim 8, wherein deleting an instance of an object comprises recursively deleting injections of the instance of the object.

10. The method of claim 8, wherein deleting an instance of an object comprises invoking any pre-destroy methods of the instance of the object, then recursively destroying injections to the instance of the object, then deleting the instance of the object, and then invoking any post-destroy methods of the instance of the object.

11. A non-transitory tangible computer readable storage medium having stored thereon a computer program implementing an Inversion of Control Container (IoCC), the computer program including a set of instructions which, when executed by a computer, cause the computer to perform a method comprising the steps of:
identifying a set of containing objects used to implement a Graphical User Interface of an application client, each containing object having at least one respective dependency;
determining a respective generator for each respective dependency;
generating a wiring graph in which the nodes of the wiring graph are the containing objects and the generators, and the edges of the graph link each respective containing object to a respective generator based on a resolved dependency; and
using the wiring graph, at runtime, to recursively create instances of objects to be wired to software objects within the IoCC.

12. The non-transitory tangible computer readable storage medium of claim 11, wherein the containing objects are base classes, and wherein the respective dependencies are injection points to the base class.

13. The non-transitory tangible computer readable storage medium of claim 11, wherein the respective generators are classes, producer methods, or producer fields.

14. The non-transitory tangible computer readable storage medium of claim 11, wherein the wiring graph is an edge-labeled, directed graph represented by an adjacency list in which the nodes of the wiring graph are either classes or producer-method return types or producer-field types.

15. The non-transitory tangible computer readable storage medium of claim 11, wherein the step of using the wiring graph, at runtime, to create instances of objects comprises, for each instance of an object to be created, selecting an base class of the instance to be created, determining a location of the base class where the base class is included as a vertex in the wiring graph, determining a set of edges leading from the vertex to a set of generators, and recursively visiting each generator to create a respective injection into the instance of the object to be created from the base class.

16. The non-transitory tangible computer readable storage medium of claim 15, wherein the step of using the wiring graph, at runtime, to create instances of objects comprises implementing a depth-first traversal of the wiring graph starting at the location of the base class where the base class is the vertex in the wiring graph.

17. The non-transitory tangible computer readable storage medium of claim 16, further comprising marking each node that is visited during the depth-first traversal of the wiring graph black and, after creating the instance of the object from the base class, marking each node that was visited during the depth-first traversal of the wiring graph white.

18. The non-transitory tangible computer readable storage medium of claim 11, further comprising using the wiring graph, at runtime, to delete instances of objects that were previously created and wired to software objects within the IoCC.

19. The non-transitory tangible computer readable storage medium of claim 18, wherein deleting an instance of an object comprises recursively deleting injections of the instance of the object.

20. The non-transitory tangible computer readable storage medium of claim 18, wherein deleting an instance of an object comprises invoking any pre-destroy methods of the instance of the object, then recursively destroying injections to the instance of the object, then deleting the instance of the object, and then invoking any post-destroy methods of the instance of the object.
